(19) United States
(12) Patent Application Publication
(10) Pub. No.: US 2007/0285105 A1
(43) Pub. Date: Dec. 13, 2007

(54) Methods and Apparatuses for Trimming Circuits

(76) Inventors: Steven Wayne Bergstedt, Winchester, KY (US); John Glenn Edelen, Versailles, KY (US); Carson Allen Fischer, Georgetown, KY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(21) Appl. No.: 11/421,820

(22) Filed: Jun. 2, 2006

(51) Int. Cl. G01R 31/04

(52) U.S. Cl. 324/538

(57) ABSTRACT

The inventions relate to methods for trimming integrated circuits. Various embodiments include providing a method to trim an integrated circuit wherein trim data is stored in an on-board memory and then sent off of the circuit to be operated on by an external device. Corresponding trim data is then sent back to the integrated circuit in order to potentially modify the function of one or more analog devices along the circuit. Other embodiments include methods for trimming integrated circuits wherein trim data is stored in an on-board memory and retrieved using an on-board sequencer. The retrieved data is used to modify a function of one or more analog devices on the integrated circuit.

### FIELD

This invention relates to apparatus and methods for modifying the function of an analog device on an integrated circuit. More particularly in one embodiment, the invention relates to the field of trimmable integrated circuits and methods for trimming integrated circuits.

### BACKGROUND AND SUMMARY OF THE INVENTION

Two common goals in integrated circuit manufacturing are to (1) minimize fabrication costs and (2) make integrated circuits that are capable of tolerating post fabrication processing. The costs associated with making integrated circuits often rises when attempting to improve characteristics such as more accurate voltage and current references, A/D converters, temperature sensing components, pulse extension control components and more stable regulator circuits. Trimming fabricated circuits is known in the art of integrated circuit manufacturing as one means to attempt to minimize these costs. The process of trimming can be described as tuning an output or other function of a circuit after fabrication of that circuit. Circuit trimming can be used, for example, when the output of a circuit falls outside of predetermined tolerance ranges for acceptable circuit performance. Instead of making changes to, for example actual transistors and transistor characteristics in the integrated circuit during fabrication (i.e., increasing fabrication costs), such a circuit may be trimmed so that its output is within the range of tolerance.

In one such conventional approach to trimming, after post-fabrication processing is complete or substantially complete, integrated circuits maybe tested to determine whether the components (typically analog devices) are operating within pre-defined tolerance values. When such testing reveals that one or more components of the integrated circuit are operating outside of pre-defined tolerance values, trim data is recorded in the nonvolatile memory component to give the integrated circuit the capability of selectively modifying the function of any integrated circuit components performing outside of the pre-defined tolerance values (e.g., changing a resistance in a regulator).

In the case of a micro-fluid ejection heater chip for a micro-fluid ejection device, the heater chip must undergo, for example, etching to form an ink via and other fluidic flow features. Such etching can be in the form of deep reactive ion etching (DRIE), often including wafer charging, wafer cleaning, and other stresses related to the packaging of the integrated circuit. These activities have been shown to shift transistor thresholds, thereby directly affecting the performance of the micro-fluid ejection heater chip as a whole. There is, therefore, a continuing need to formulate new integrated circuit structures and integrated circuit processing methods to further utilize the benefits of post-fabrication trimming in more cost-effective models.

Various embodiments of the invention disclosed herein involve trimming integrated circuits after circuit fabrication. An exemplary embodiment of the invention provides a method for modifying a function of an analog device in an integrated circuit, the method including receiving data on a line used for addressing at least one of a plurality of actuators of the integrated circuit, retrieving data that can be used to modify a function of an analog device of the integrated circuit from memory of the integrated circuit based on the received data, and modifying a function of the analog device in response to the retrieved data.

In one embodiment of the invention the retrieved data is transferred to an external device that is separate from the integrated circuit and that controls the integrated circuit, and data corresponding to the retrieved data is transmitted from the external device to the integrated circuit.

Other embodiments of the methods described above include use of a sequencer for retrieving the data. In a particular embodiment, a method is described including using a sequencer to retrieve data that can be used to modify a function of an analog device of an integrated circuit from memory of the integrated circuit, using the sequencer to select at least one of a plurality of registers, shifting the retrieved data to the at least one selected register, and modifying the function of the analog device in response to the retrieved data. In a related embodiment, the retrieved data is also transferred to an external device and corresponding data is received back from the external device. The external device controls the integrated circuit and is separate from the integrated circuit.

In an exemplary embodiment using a sequencer, the external device might be a print controller with the integrated circuit receiving print data from the external device. The integrated circuit receives the print data on a line that the integrated circuit uses to receive the retrieved data from the external device. In a related embodiment, the retrieved data is encrypted before it is sent to the external device. The methods described using a sequencer may also include retrieving trim data from the memory in response to receiving address data on a line used for addressing at least one of a plurality of actuators of the integrated circuit. The data received by the integrated circuit may be in serial form. In another embodiment using a sequencer, the sequencer retrieves the data from the memory in response to an event such as a power-up request. In an exemplary embodiment, the sequencer is used to drive an address register to index the memory.

### BRIEF DESCRIPTION OF THE DRAWINGS

Further advantages of the invention are apparent by reference to the detailed description when considered in conjunction with the figures, which are not to scale so as to more clearly show the details, wherein like reference numbers indicate like elements throughout the several views, and wherein:

FIG. 1 is a schematic view illustrating an integrated circuit used in at least one embodiment of the method described herein.

FIG. 2 is a schematic view illustrating an integrated circuit used in at least one embodiment of the method described herein, the integrated circuit having a plurality of serial data registers linked together in series.

FIG. 3 is a schematic view illustrating an integrated circuit used in at least one embodiment of the method described herein, the integrated circuit having a sequencer.

### DETAILED DESCRIPTION OF EXEMPLARY EMBODIMENTS OF THE INVENTION

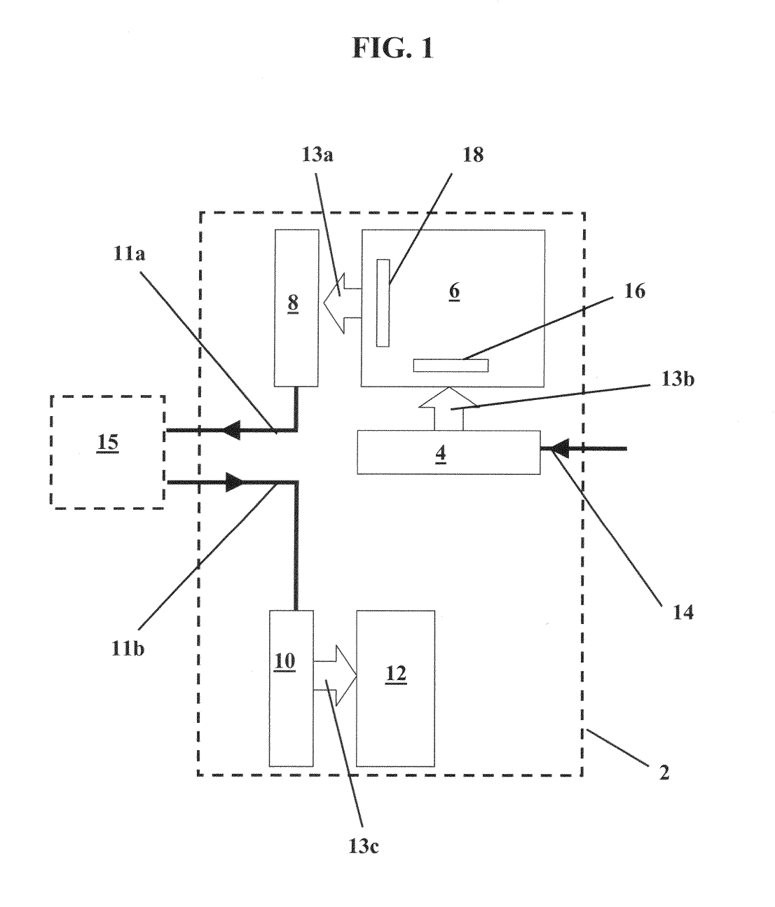

An overview of an integrated circuit 2 as used in various embodiments of the invention is shown in Figure. The boundaries of the integrated circuit 2 are drawn as dotted lines to show that the parts described hereafter may be arranged in many different formations. Integrated circuit 2 is one exemplary embodiment of many circuit embodiments used with the methods described herein. The integrated circuit 2 includes an address register 4, a memory 6, a serial shift register 8, a serial data register 10, and a trim register 12. Serial lines 11a, 11b, and 14 are designated as solid black arrows and broad/outlined arrows 13a, 13b, and 13c designate parallel lines. However, it should be understood by those skilled in the art that any combination of serial and parallel lines could be used to accomplish the methods described herein, so the choice of serial lines and parallel lines represented in FIG. 1 is not meant to be limiting.

The address register 4 is capable of receiving incoming data in serial form from a source external to the integrated circuit 2. When received by the integrated circuit 2, the incoming data arrives via the first line 14, which may also be the line by which the integrated circuit receives data for addressing at least one of a plurality of actuators (not shown) of the integrated circuit. In an exemplary embodiment, line 13a and data register 10, for example, may also be used for addressing at least one of a plurality of actuators of the integrated circuit. For example, in an exemplary embodiment, with the exception of trim register 12 (and associated trimming circuits), the embodiment illustrated in FIG. 1 represents an integrated circuit that may be conventionally used as, for example, as part of an inkjet printhead heater chip. Accordingly, such a conventional heater chip might be easily and advantageously modified in accordance with teachings of the present inventions, such as by adding trim register 12 (and associated trimming circuits).

The address register 4 converts the incoming serial data into parallel data and uses the parallel data to index memory 6.Memory 6 contains memory inputs 16 for receiving indexing data (e.g., in parallel form) from the address register 4. When the indexing data is received, corresponding trim data stored in memory 6 is transfered out of memory 6. Memory 6 further contains memory outputs 18 for transferring trim data (e.g., in parallel form) from memory 6.

Memory 6 has, at least in part, digital memory capacity in the form of for example nonvolatile memory. For instance, memory 6 may be composed of one or more blocks of fuses. However, those skilled in the art appreciate that any means of storing nonvolatile memory in the special parameters of an integrated circuit like the embodiments disclosed herein will suffice including, but not limited to, EPROM, EEPROM, Flash memory and anti-fuse devices. Trim data may be stored in memory 6 after or during final stages of the fabrication of integrated circuit 2. In an exemplary embodiment, trim data is distributed through the integrated circuit 2 upon or shortly after an event (such as a power up command).

Trim data is retrieved and sent from memory 6, through memory interface 8 for example a serial shift register. Interface 8 may transform the trim data from parallel form to serial form. The trim data in serial form maybe sent to an external device 15 over serial lines 11. The external device 15 might be the same device used to communicate data to the circuit 2 via serial line 14. In an exemplary embodiment the external device 15 might verify the trim data and/or process the trim data to produce corresponding trim data. For example the external device 15 might modify the trim data in relation to a mode of operation of the external device and or an application that is being processed by the external device. In an exemplary embodiment for example, the external device 15 might be a print controller wherein the print controller modifies trim data as a function of operating information, such as ink usage. After the external device has processed and/or verified the trim data (if applicable) the corresponding trim data (which may be identical to the trim data) is sent back to the integrated circuit 2 (e.g., in serial form) to serial data register 10. In an exemplary embodiment, this data may be sent to the integrated circuit using a line that is used to send and/or receive other data operated on by the integrated circuit 2 (e.g., print data, such as address or primitive data).

Serial data register 10 receives the corresponding trim data from the external device 15 Substantially when the serial data register 10 receives a latch command (e.g., from the external device 15), the corresponding trim data in the serial data register 10 is latched to the trim register 12 and temporarily stored. The corresponding trim data is transferred (e.g., in parallel form) from the serial data register 10 to the trim register 12. The “latch” command, as mentioned above, may be accomplished by using an unused input combination of serial data from the external device (e.g., LOAD+CLK+FIRE, wherein “LOAD” represents a data loading command, “CLK” represents a clock or time value command, and “FIRE” represents an action command). Since these three commands are not otherwise used together simultaneously for normal operation of integrated circuit 2, their use together in combination for the latching command to transfer trim data to the trim register 12 is convenient.

The specific information contained in the trim data maybe used to modify one or more functions of one or more analog devices. For example, if testing of a particular integrated circuit revealed that a specific analog device in the integrated circuit operated with a voltage measurement that was 0.1 volts too high (based on pre-selected tolerance values for that particular module), the trim data associated with that particular analog device could be used to alter the analog device to function at least 0.1 volts less during operation of the integrated circuit. As long as the corresponding trim data remains in the trim register 12 during operation of the integrated circuit 2, the function of the analog device in the integrated circuit will be modified based on the corresponding trim data. Therefore this embodiment as well as others described herein allow for integrated circuit 2 to be manipulated after fabrication and after processing such as to fine tune its function(s) without making physical changes to the characteristics of individual devices such as transistors or other vital parts of the integrated circuit 2. By using embodiments such as those described above, fabrication costs can remain low as (1) circuit components like transistors need not be made more robust and (2) fabricated integrated circuits can be “fixed” or “tweaked” after non-fatal damage or errors occur in the circuit.

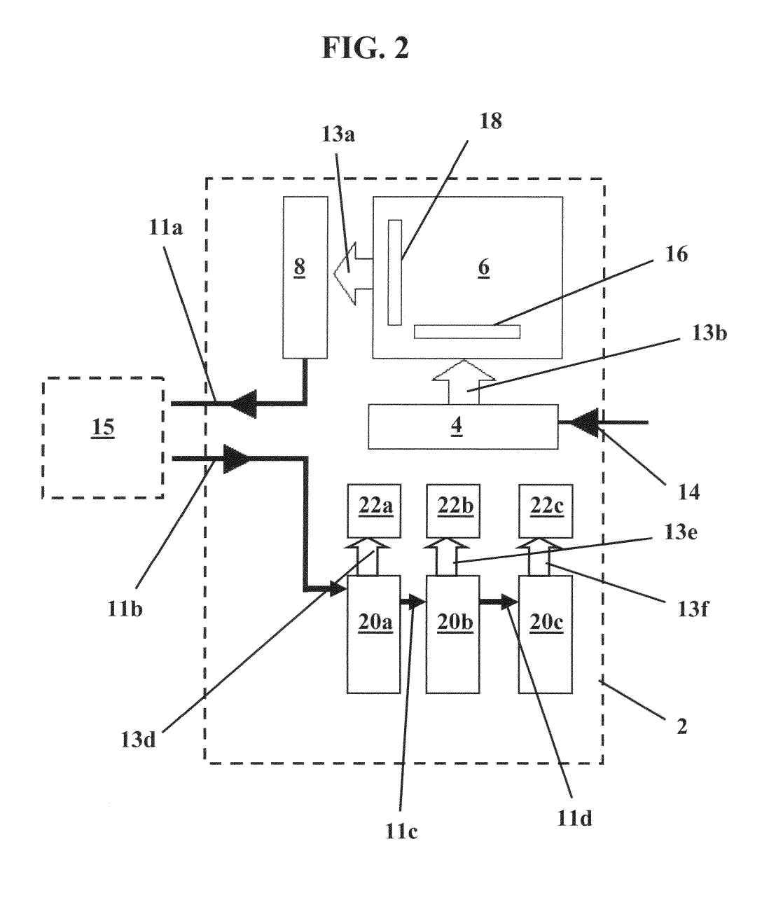

Another exemplary method involves a plurality of serial data registers 20a, 20b, and 20c connected in series as shown in FIG. 2. Each of the serial data registers (20a, 20b, and 20c) is also in communication with a trim register 22a, 22b, and 22c, respectively, as shown in FIG. 2. First serial data register 20a is in communication with first trim register 22a ; second serial data register 20b is in communication with second trim register 22b; and third serial data register 20c is in communication with third trim register 22c.

As with certain previous embodiments discussed with relation to FIG. 1, corresponding trim data (e.g., in serial form) is sent from the external device 15 along serial line 11b to integrated circuit 2. A first portion of corresponding trim data is sent to the first serial data register 20a. The first portion of corresponding trim data in first serial data register 20a is then shifted to the second serial data register 20b along serial line 11c, while a second portion of corresponding trim data falls in behind and is transferred to the first serial data register 20a. Subsequently, the first portion of corresponding trim data in second serial data register 20b is shifted to a third serial data register 20c along serial line 11d. As the first portion of corresponding trim data shifts to third serial data register 20c, the second portion of corresponding trim data falls in behind and is shifted to second serial data register 20b while a third portion of corresponding tri n data is shifted to the first serial data register 20a. When the corresponding trim data is in place for proper latching to trim registers 22a, 22b, and 22c, a latch command (e.g., one sent from the external device 15) to the serial data registers 20a, 20b, and 20c and the corresponding trim data is latched to trim registers 22a, 22b, and 22c, respectively, along parallel lines 13d, 13e, and 13f, respectively. This embodiment illustrates the use of multiple serial data registers connected in series.

Another set of exemplary embodiments involves using a sequencer. For example, data may be retrieved from memory in the integrated circuit using a sequencer. The retrieved data may or may not be then transferred to an external device, such as one that is separate from and controls the integrated circuit. If transferred to an external device, the retrieved data is also received by the integrated circuit from the external device. Function of at least one analog device of the integrated circuit is then modified in response to the retrieved data. In an exemplary embodiment, the sequencer is used to select at least one of a plurality of registers in an integrated circuit. The sequencer then shifts the retrieved data to the at least one selected register.

In a simplified embodiment, a method for modifying a function of an analog device in an integrated circuit includes (i) receiving data on a line used for addressing at least one of a plurality of actuators of an integrated circuit wherein the data is received at a sequencer, (ii) indexing the memory of the integrated circuit using an address register that is driven by the sequencer, (iii) retrieving data that can be used to modify a function of an analog device of the integrated circuit from memory of the integrated circuit based on the received data, and (iv) modifying a function of the analog device in response to the retrieved data.

Another exemplary embodiment of the invention involves an integrated circuit, at least one analog device in the integrated circuit, at least one actuator of the integrated circuit, a memory in the integrated circuit, and a sequencer. An exemplary method for use with the same may involve (i) using the sequencer to retrieve data that can be used to modify a function of an analog device of the integrated circuit from memory of the integrated circuit, (ii) selecting at least one of a plurality of registers, (iii) shifting the retrieved data to the at least one selected register, and (iv) modifying the function of at least one analog device in response to the retrieved data. This exemplary method may, in certain other embodiments, include transferring the retrieved data to an external device and receiving the retrieved data from the external device. The retrieved data may, for example, be transferred and received in serial form. The transferred data may also be encrypted before it is transferred to the external device and received by the external device. In certain related embodiments, the external device might control the integrated circuit and be separate from the integrated circuit. In an exemplary embodiment, the external device is a print controller and the data received from the external device is received on the same line as print data.

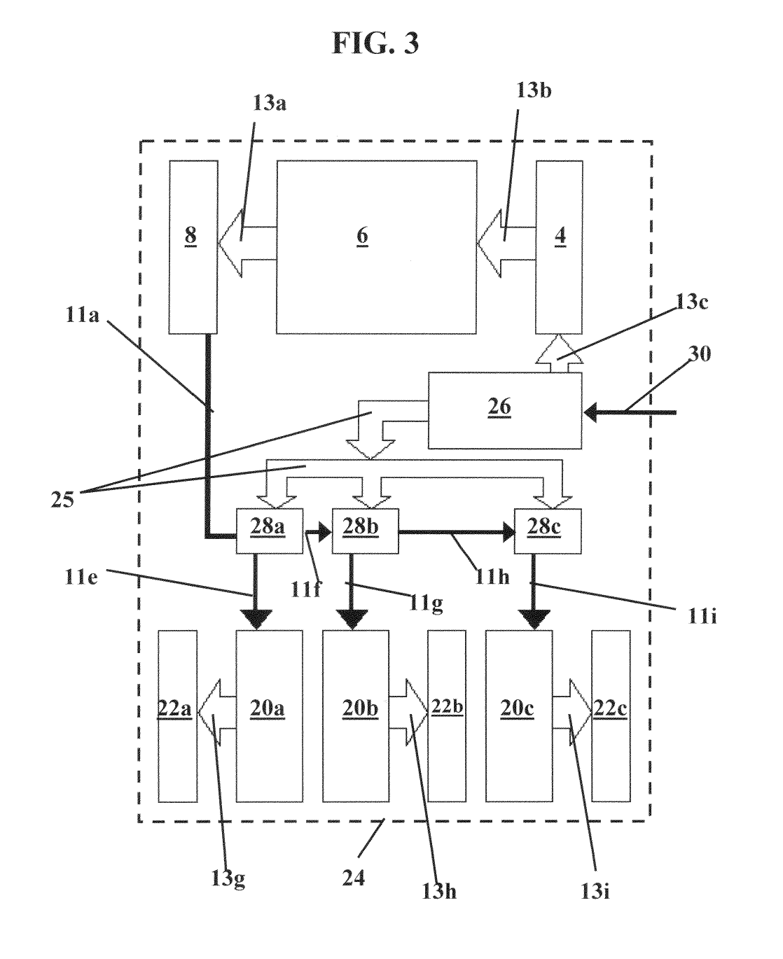

One example of a circuit with a sequencer used in various methods described herein is illustrated in FIG. 3. The boundaries of an integrated circuit 24 are drawn as dotted lines to show that the parts described hereafter maybe arranged in many different formations within the dotted lines as long as such parts remain on the integrated circuit 24. As with FIG. 1 and FIG. 2, the solid black lines 11a, 11e, 11f, 11h, 11i, and 30 represent lines for transferring data in serial form and the broad outlined lines 13a, 13b, 13c, 13g, 13h, and 13i represent lines for transferring data in parallel form. However, any suitable combination of serial and parallel lines could be used to accomplish the methods described herein so that the choice of serial lines and parallel lines represented in FIG. 3 is not meant to be limiting. The lines 25 between a sequencer 26 and a plurality of decode registers 28 represent communication between the sequencer 26 and the decode registers 28. The circuit includes the sequencer 26, an address register 4, a memory 6, a shift register 8, the plurality of decode registers 28a, 28b, and 28c, a plurality of serial data registers 20a, 20b, and 20c, and a plurality of trim registers 22a, 22b, and 22c. In one embodiment, the sequencer is initiated by an event, such as a power-up request or other event external to the integrated circuit 24. Alternatively, data may be received via address line 30 at the sequencer 26. In an exemplary embodiment, the data is in serial form, and m ay include at least one bit that can be set to represent that the data is to be used for a trimming operation. Address line 30 may also be used for addressing at least one of a plurality of actuators (e.g., heater resistors) of the integrated circuit 24. The sequencer 26 indexes through a series of addresses and sends the address data to the address register 4, thereby driving the address register 4.

The address data is used to index memory 6. In response to the sequencer 26, trim data is retrieved and transferred from memory 6 to shift register 8. The shift register 8 converts the trim data from parallel form to serial form. The trim data may then be transferred to decode register 28a. The sequencer 26 is in communication with all of the decode registers 28 such that the trim data is shifted through to all decode registers 28 until the trim data is ready for transfer to the serial data registers 20. After the trim data is transferred to the serial data registers 20, a latch command may be used to initiate latching of the trim data into each of the respective trim registers 22. For example, substantially as long as trim data remains latched into trim register 22b, the function of the one or more analog devices associated with trim register 22b will be modified based on the latched trim data.

The foregoing description of certain exemplary embodiments of the present invention has been provided for purposes of illustration only, and it is understood that numerous modifications or alterations may be made in and to the illustrated embodiments without departing from the spirit and scope of the invention as defined in the following claims.

What is claimed is:

1. A method for modifying a function of an analog device in an integrated circuit comprising:
a. receiving data on a line used for addressing at least one of a plurality of actuators of an integrated circuit;
b. retrieving data that can be used to modify a function of an analog device of the integrated circuit from memory of the integrated circuit based on the received data; and
c. modifying a function of the analog device in response to the retrieved data.

2. The method of claim 1, further comprising indexing the memory of the integrated circuit using an address register.

3. The method of claim 2, wherein the address register receives the data on the line used for addressing.

4. The method of claim 2, wherein a sequencer of the integrated circuit receives the data on a line used for addressing and drives the address register.

5. A method for modifying a function of an analog device in an integrated circuit, comprising:
a. receiving data on a line used for addressing at least one of a plurality of actuators of an integrated circuit;
b. retrieving data that can be used to modify a function of an analog device of the integrated circuit from memory of the integrated circuit based on the received data;
c. transferring the retrieved data to an external device that is separate from the integrated circuit and that controls the integrated circuit;
d. receiving corresponding retrieved data from the external device; and
e. modifying the function of the analog device in response to the corresponding retrieved data.

6. The method of claim 5, wherein the retrieved data is processed by the external device.

7. The method of claim 6, wherein the retrieved data is verified by the external device.

8. A method for modifying a function of an analog device in an integrated circuit comprising:
a. retrieving data that can he used to modify a function of an analog device of an integrated circuit from memory of the integrated circuit;
b. transferring the retrieved data to an external device that is separate from and controls the integrated circuit;
c. receiving corresponding retrieved data from the external device; and
d. modifying the function of the analog device in response to the corresponding retrieved data.

9. A method for modifying a function of an analog device in an integrated circuit, comprising:
a. retrieving data that can be used to modify a function of an analog device of an integrated circuit from memory of the integrated circuit;
b. transferring the retrieved data to an external device that is separate from and controls the integrated circuit;
c. receiving corresponding retrieved data from the external device; and
d. modifying the function of the analog device in response to the corresponding retrieved data, wherein the retrieved data is retrieved from memory by using a sequencer of the integrated circuit.

10. The method of claim 9, further comprising:
a. using the sequencer to select at least one of a plurality of registers; and
b. shifting the retrieved data received from the external device to the at least one selected register.

11. A method for modifying a function of an analog device in an integrated circuit, comprising:
a. using a sequencer to retrieve data that can be used to modify a function of an analog device of an integrated circuit from memory of the integrated circuit;
b. using the sequencer to select at least one of a plurality of registers;
c. shifting the retrieved data to the at least one selected register; and
d. modifying the function of the analog device in response to the retrieved data.

12. The method of claim 11 further comprising:
a. transferring the retrieved data to an external device that is separate from and controls the integrated circuit;
b. receiving corresponding retrieved data from the external device.

13. The method of claim 12, wherein the external device is a print controller, further comprising receiving print data from the external device, wherein the integrated circuit receives the print data on a line that the integrated circuit uses to receive the retrieved data from the external device.

14. The method of claim 12, wherein transferring the retrieved data and receiving the corresponding retrieved data comprises serially transferring the retrieved data and serially receiving the corresponding retrieved data.

15. The method of claim 12, further comprising encrypting the retrieved data, and wherein transferring the retrieved data comprises transferring the encrypted retrieved data.

16. The method of claim 11, wherein the sequencer retrieves the data from the memory in response to receiving data on a line used for addressing at least one of a plurality of actuators of the integrated circuit.

17. The method of claim 16, wherein the received data comprises serial data.

18. The method of claim 11, wherein the sequencer retrieves the data from the memory in response to an event.

19. The method of claim 18, wherein the event comprises a power-up request.

20. The method of claim 11, wherein using the sequencer to retrieve data comprises driving an address register with the sequencer to index the memory.
